(19) United States
(12) Patent Application Publication
(10) Pub. No.: US 2009/0233443 A1
(43) Pub. Date: Sep. 17, 2009

(54) SUBSTRATE MOUNTING TABLE, SUBSTRATE PROCESSING APPARATUS AND TEMPERATURE CONTROL METHOD

(75) Inventor: Yasuharu SASAKI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/203,402

(22) Filed: Sep. 3, 2008

Related U.S. Application Data
(60) Provisional application No. 60/991,813, filed on Dec. 3, 2007.

(30) Foreign Application Priority Data
Sep. 3, 2007 (JP) 2007-227708

(51) Int. Cl. H01L 21/302

(52) U.S. Cl. 438/689; 156/345.52

(57) ABSTRACT

A substrate mounting table for mounting a substrate in a substrate processing apparatus, includes a table body having a substrate mounting surface. An annular peripheral ridge portion is formed on the substrate mounting surface of the table body. The annular peripheral ridge portion makes contact with a peripheral edge portion of the substrate and forms a closed space for circulation of a heat transfer gas below the substrate, when the substrate is mounted on the substrate mounting surface of the table body. The table body has a heat transfer gas inlet port formed in a peripheral edge region of the substrate mounting surface, a heat transfer gas outlet port formed in a central region of the substrate mounting surface, and a flow path formed on the substrate mounting surface for forming a conductance C when the heat transfer gas flows from the inlet port to the outlet port.

### FIELD OF THE INVENTION

The present invention relates to a substrate mounting table for mounting thereon a substrate such as a semiconductor wafer or the like, a substrate processing apparatus for performing processes such as etching and the like on a substrate mounted on the substrate mounting table, and a temperature control method for controlling the temperature of a substrate mounted on the substrate mounting table.

### BACKGROUND OF THE INVENTION

In a plasma etching process, a mounting table for mounting thereon a semiconductor wafer (hereinafter, merely referred to as “wafer” or “substrate”) to be processed is provided within a chamber. The wafer is electrostatically attracted and kept in place by means of an electrostatic chuck forming an upper portion of the mounting table. The wafer is subjected to plasma etching by generating plasma of a processing gas.

Since the wafer is heated from above in such a plasma processing apparatus, a coolant flow path is provided inside the mounting table to cool the same and a heat transfer gas such as He gas or the like is introduced into a gap between the mounting table and the backside of the wafer to facilitate cooling of the wafer.

Japanese Patent Laid-open Publication No. 2000-317761 discloses a technique of cooling the wafer using the heat transfer gas wherein a plurality of convex dots is formed on an attracting surface of an electrostatic chuck forming an upper portion of a mounting table, and the amount of heat dissipated from the wafer is changed by controlling the height of the convex dots and the pressure of the heat transfer gas, thereby controlling the temperature of the wafer.

Further, Japanese Patent Laid-open Publication No. 2001-274228 discloses a technique of enhancing temperature controllability in a high temperature zone of a wafer by setting the height of protrusions within a range of from 1 μm to 10 μm and allowing the protrusions to make contact with a 1% area of the wafer.

In case of merely forming the protrusions on a substrate mounting surface as mentioned above, the heat transfer gas is hard to spread over the whole surface of the wafer if the protrusions have a reduced height. As a result, a problem is posed in that it becomes difficult to uniformly control the temperature of the wafer.

In contrast, if the height of the protrusions is increased, the quantity of heat transferred from the wafer to the mounting table is reduced. This poses a problem in that it becomes difficult to control the temperature of the wafer as desired.

As the wafer grows bigger, there occurs a difference in the balance of input heat and output heat between the center and periphery thereof. This leads to a problem in that it is difficult to maintain the whole surface of the wafer at a uniform temperature. In general, the center of the wafer is easy to cool but the periphery thereof is cooled insufficiently. For that reason, the degree of cooling needs to be made different between the center and periphery of the wafer in order to control the whole surface of the wafer at a uniform temperature.

As one of the methods for making the cooling degree of the substrate different from region to region, there has been proposed a method in which a mounting table is divided into a plurality of zones and a cooling gas is differently supplied to the respective zones (see Japanese Patent Laid-open Publication No. 2006-156938).

In other words, an annular peripheral ridge portion is formed on the surface of the mounting table. The closed space formed between the substrate and the surface of the mounting table is divided into an inner zone and an outer zone portion. Heat transfer gas introduction ports are provided in the inner and outer zones. With this arrangement, it becomes possible to apply different pressures to the respective zones divided by the annular peripheral ridge portion.

In the method in which the annular peripheral ridge portion is formed in the mounting table to divide the cooling area of the substrate into the plurality of zones, the mounting table makes contact with the substrate in the annular peripheral ridge portion that divides the zones. Thus, the amount of heat dissipated from the substrate through this contact portion becomes greater than the amount of heat dissipated in other portions. As a consequence, the temperature of the substrate in the vicinity of the contact portion is made lower than the temperature in other portions. This is problematic in that an abnormality may appear in the substrate properties.

### SUMMARY OF THE INVENTION

The present invention provides a substrate mounting table which is superior in the controllability of temperature of an object substrate and is free from an abnormality such as an abrupt change in the heat dissipation amount in a local area of the substrate or the like, a substrate processing apparatus incorporating the substrate mounting table and a substrate temperature control method.

In accordance with a first aspect of the present invention, there is provided a substrate mounting table for mounting a substrate in a substrate processing apparatus, including: a table body having a substrate mounting surface; and an annular peripheral ridge portion formed on the substrate mounting surface of the table body for making contact with a peripheral edge portion of the substrate and for forming a closed space for circulation of a heat transfer gas below the substrate, when the substrate is mounted on the substrate mounting surface of the table body; wherein the table body has a heat transfer gas inlet port formed in one of a peripheral edge region and a central region of the substrate mounting surface, a heat transfer gas outlet port formed in the other of the peripheral edge region and the central region of the substrate mounting surface, and a flow path formed on the substrate mounting surface for forming a conductance C when the heat transfer gas flows from the inlet port to the outlet port.

Preferably, the conductance C is within a desired range and is defined by equation (1):

C (m³/sec)=Q/ΔP (1),

where the Q is a mass flow rate (Pa·m³/sec) of the heat transfer gas and the ΔP is a differential pressure (Pa) between the inlet port and the outlet port.

In this regard, it is preferred that the flow path is formed by connecting protrusion bodies with connection members and concentrically arranging the same on the substrate mounting surface. It is also preferred that the protrusion bodies are provided in close proximity to the substrate without contacting therewith. The heat transfer gas flows through a gap between the protrusion bodies and the substrate. The conductance is decided by the gap.

It is preferred that the flow path is formed by connecting the protrusion bodies with connection members and concentrically arranging the same in plural lines, each of the protrusion bodies having thereon a relatively small jut that makes contact with the substrate.

This helps reduce generation of an abnormality in the substrate temperature, because the small jut makes contact with the substrate. Furthermore, the small jut serves to stably maintain the gap between the upper ends of the protrusion bodies and the substrate. Since the flow of the heat transfer gas can be easily controlled by adjusting the width and height of the small jut, it is easy to adjust the conductance.

In accordance with a second aspect of the present invention, there is provided a substrate mounting table for mounting a substrate in a substrate processing apparatus, including: a table body having a substrate mounting surface; and an annular peripheral ridge portion formed on the substrate mounting surface of the table body for making contact with a peripheral edge portion of the substrate and for forming a closed space for circulation of a heat transfer gas below the substrate, when the substrate is mounted on the substrate mounting surface of the table body, wherein the table body includes: a heat transfer gas inlet port and a heat transfer gas outlet port one of which is formed at a position spaced by a distance r away from the center point of the substrate mounting surface and the other one is formed in a peripheral edge region of the substrate mounting surface; a flow path formed on the substrate mounting surface for forming a conductance C when the heat transfer gas flows from the inlet port to the outlet port; and a plurality of dot-like protrusions arranged in a range between the center point of the substrate mounting surface and the position spaced by the distance r away from the center point.

Preferably, the conductance C is within a desired range and is defined by equation (1):

C (m³/sec)=Q/ΔP (1),

where the Q is a mass flow rate (Pa·m³/sec) of the heat transfer gas and the ΔP is a differential pressure (Pa) between the inlet port and the outlet port.

Preferably, the flow path is formed by flow path forming members concentrically arranged in plural lines, each of the flow path forming members including protrusion bodies and connection members interconnecting the protrusion bodies, the protrusion bodies being provided in close proximity to the substrate without contacting therewith.

Preferably, the flow path is formed by flow path forming members concentrically arranged in plural lines, each of the flow path forming members including protrusion bodies and connection members interconnecting the protrusion bodies, each of the protrusion bodies having thereon a relatively small jut that makes contact with the substrate.

With this configuration, for example, the pressure of the heat transfer gas in the area between the inlet port formed in the peripheral edge region and the outlet port formed in a position spaced by the distance r away from the center point is gradually reduced from the inlet port toward the outlet port.

On the other hand, in the area between the outlet port and the center point, the heat transfer gas does not flow except the initial state in which the gas is filled. Therefore, the gas pressure in that area is kept constant. Although it is impossible conventionally to create areas (zones) of different pressures unless partition walls are provided, the present invention is capable of creating areas of different pressures without having to providing the partition walls.

In accordance with a third aspect of the present invention, there is provided a substrate mounting table for mounting a substrate in a substrate processing apparatus, including: a table body having a substrate mounting surface; an annular peripheral ridge portion formed on the substrate mounting surface of the table body for making contact with a peripheral edge portion of the substrate and for forming a closed space for circulation of a heat transfer gas below the substrate, when the substrate is mounted on the substrate mounting surface of the table body; and a plurality of generally circular partition walls concentrically arranged within the closed space for forming a flow path of the heat transfer gas, wherein the table body includes: a heat transfer gas inlet port formed in one of a peripheral edge region and a central region of the substrate mounting surface; and a heat transfer gas outlet port formed in the other of the peripheral edge region and the central region of the substrate mounting surface, and wherein each of the partition walls has a cutout through which the heat transfer gas flows.

Preferably, the cutout portion is formed in a position farthest from the inlet port or the outlet port. In case of forming the cutout portion in plural numbers in each of the partition wall, it is preferred that the number of cutout portions is identical in the neighboring partition walls and further that the cutout portions of one partition wall are arranged farthest from the cutout portions of another neighboring partition wall. This makes it possible to form a heat transfer gas flow path with a desired conductance C.

Preferably, the conductance C is within a desired range and is defined by equation (1):

C (m³/sec)=Q/ΔP (1),

where the Q is a mass flow rate (Pa-m³/sec) of the heat transfer gas and the ΔP is a differential pressure (Pa) between the inlet port and the outlet port.

Preferably, the partition walls are in close proximity to the substrate without contacting therewith. Further, the partition walls may be in contact with the substrate.

Preferably, the conductance C is in a range of from 3×10⁻⁸ m³/sec to 3×10⁻⁴ m³/sec, and more preferably, from 3×10⁻⁷ m³/sec to 3×10⁻⁵ m³/sec. Further, it is preferred that a heat transfer gas pressure difference between the inlet port and the outlet port falls within a range of from 10 Torr to 40 Torr.

More preferably, the flow path is formed to ensure that the heat transfer gas pressure difference between the inlet port and the outlet port falls within the range of 10 Torr to 40 Torr when the heat transfer gas flows at a flow rate of 1 sccm to 100 sccm. In this way, with a small amount of the heat transfer gas, it is possible to properly provide a pressure difference of the heat transfer gas.

In accordance with a forth aspect of the present invention, there is provided a substrate processing apparatus including: a processing chamber for receiving a substrate, the processing chamber having an internal space kept under a reduced pressure; the aforementioned substrate mounting table provided within the processing chamber for mounting the substrate; a processing mechanism for subjecting the substrate to a specified treatment within the processing chamber; and a heat transfer gas supplying mechanism for supplying a heat transfer gas to a closed space formed between the substrate mounting table and the substrate mounted thereon.

Preferably, the substrate processing apparatus further includes a control mechanism for controlling the pressure of the heat transfer gas supplied from the heat transfer gas supplying mechanism.

In accordance with a fifth aspect of the present invention, there is provided a substrate temperature control method for controlling the temperature of a substrate using the aforementioned substrate mounting table, the method including: controlling the flow rate of a heat transfer gas to ensure that a heat transfer gas pressure difference between the inlet port and the outlet port becomes equal to 10 Torr to 40 Torr, when the conductance C is within a range of from 3×10⁻⁷ m³/sec to 3×10⁻⁵ m³/sec.

In this method, the conductance C is preferably controlled by changing the height of the gap between the concentrically arranged partition walls and the substrate which defines the flow path, and/or the number of lines of the concentrically arranged flow path.

In accordance with the present invention, it is possible to provide a substrate mounting table capable of controlling the ratio of heat dissipation amounts in the peripheral region and central region of a substrate and free from an abnormality such as an abrupt change in the heat dissipation amount in a local area of the substrate or the like, a substrate processing apparatus incorporating the substrate mounting table and a substrate temperature control method.

Furthermore, use of the present substrate mounting table makes it possible to generate a desired gas pressure difference in the mounting table with a minimum necessary amount of heat transfer gas (helium, etc.). Consequently, it is possible to control the whole substrate at a desired uniform temperature.

### BRIEF DESCRIPTION OF THE DRAWINGS

The objects and features of the present invention will become apparent from the following description of embodiments, given in conjunction with the accompanying drawings, in which:

FIGS. 1A and 1B are views showing a mounting table for a substrate to be processed in accordance with a first embodiment of the present invention;

FIGS. 2A, 2B, 3A, 3B, 4A and 4B are views illustrating the shape of dot-like protrusions formed on a mounting table surface in the first embodiment;

FIG. 5 is a view for explaining how to conduct a pressure control test in the first embodiment;

FIG. 6 is a view representing the results of a temperature measurement test in the first embodiment;

FIG. 7 is a view representing the relationship between a He pressure and a heat resistance measured within a gap;

FIGS. 8A, 8B and 8C are views showing a mounting table for a substrate to be processed in accordance with a second embodiment of the present invention;

FIGS. 9A and 9B are views showing a mounting table for a substrate to be processed in accordance with a third embodiment of the present invention;

FIG. 10 is a view showing a mounting table for a substrate to be processed in accordance with a fourth embodiment of the present invention; and

FIG. 11 is a view showing a modified example of the mounting table in accordance with the fourth embodiment of the present invention.

### DETAILED DESCRIPTION OF THE EMBODIMENTS

Hereinafter, a first embodiment of the present invention will be described with reference to the accompanying drawings.

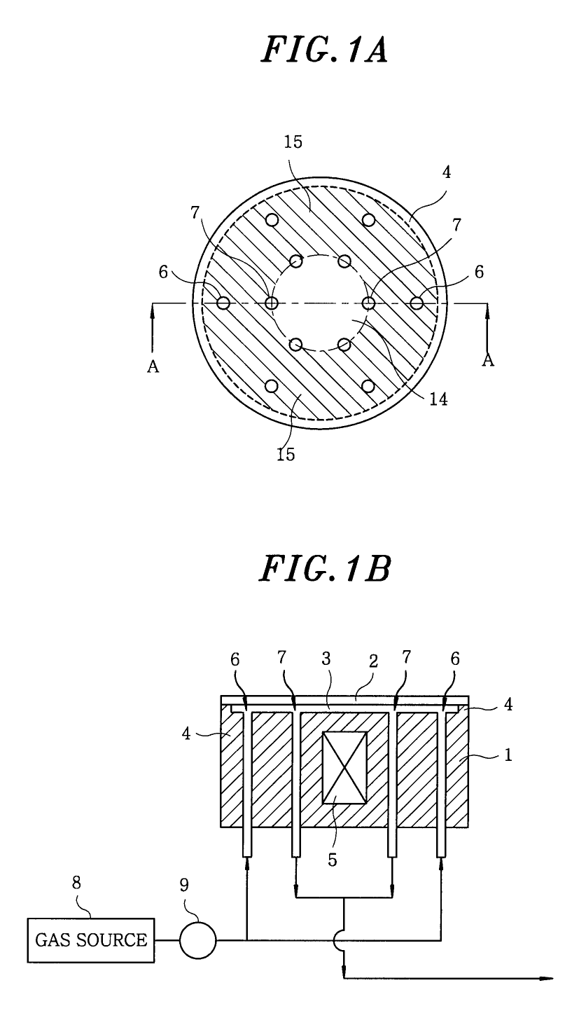

FIG. 1A is a plan view showing a substrate mounting table in accordance with the first embodiment of the present invention and FIG. 1B is a section view taken along line A-A in FIG. 1A.

A substrate (wafer) 2 to be processed is mounted on the upper portion of a mounting table 1. A depressed portion is formed in a substrate mounting surface, i.e., the surface of the mounting table 1 on which the substrate is mounted. A gap 3 is formed between the substrate mounting surface and the substrate 2.

An annular peripheral ridge portion 4 is provided along the outer periphery of the depressed portion. The peripheral ridge portion 4 serves to support the peripheral edge of the substrate 2 and also to prevent leakage of a heat transfer gas from the gap 3. The gap 3 becomes a closed space due to the presence of the peripheral ridge portion 4.

A plurality of protrusions (not shown in FIGS. 1A and 1B) is provided in the depressed portion at regular intervals. These protrusions are designed to support the substrate 2 to prevent the substrate 2 from being deformed by its own weight. Furthermore, the protrusions serve to define a flow path of the heat transfer gas and also to generate a flow resistance against the heat transfer gas. A coolant flow path 5 is provided within the mounting table 1 to control the mounting table 1 at a desired temperature.

In the mounting table 1 of the first embodiment, heat transfer gas inlet ports 6 are formed near the peripheral region of the depressed portion and heat transfer gas outlet ports 7 are formed near the central region thereof.

As shown in FIG. 1A, the inlet ports 6 include six inlet ports arranged along a concentric circle symmetrically with respect to the center relationship with one another. The outlet ports 7 are formed in the positions somewhat distant from the center of the mounting table 1 so that the gas introduced form the inlet ports 6 can be discharged therethrough. The outlet ports 7 include six outlet ports arranged along a concentric circle symmetrically with respect to the center. The number and position of the inlet ports 6 and the outlet ports 7 is not limited thereto. Furthermore, there is no need for the inlet ports 6 and the outlet ports 7 to be identical in number.

The heat transfer gas, e.g., He gas, is supplied from a gas source 8 through a flow rate controller 9 (including a gas flow rate control unit) and is distributed to the six inlet ports 6 by means of branch pipes. The heat transfer gas flowing out of the outlet ports 7 is joined together and discharged. The inlet ports are not necessarily positioned near the peripheral region of the mounting table. Contrary to the illustrated embodiment, the inlet ports may be formed near the central region of the mounting table and the outlet ports may be formed near the peripheral region thereof.

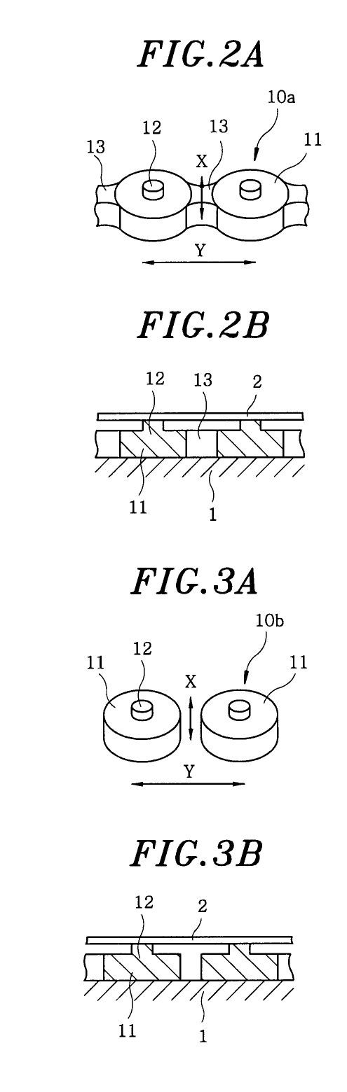

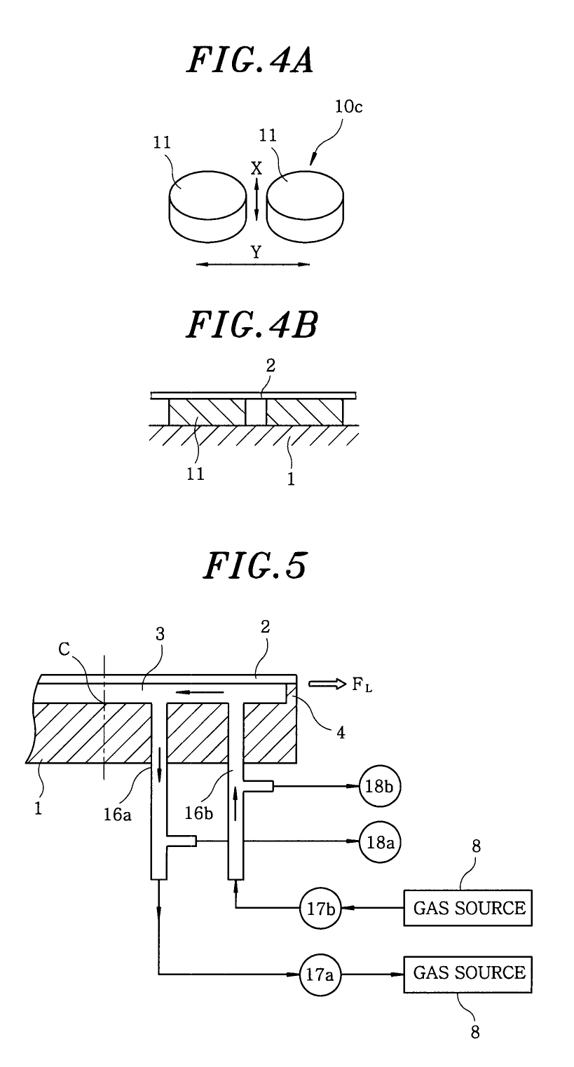

In the mounting table 1 of the present embodiment, two kinds of protrusions shown in FIGS. 2A, 2B and 3A, 3B (hereinafter, separately referred to as a “connection type” and a “non-connection type”) are used as the dot-like protrusions arranged within the gap 3. It may also be possible to use protrusions having no small jut as shown in FIGS. 4A and 4B.

FIGS. 2A and 2B show a connection type dot-like protrusion and FIGS. 3A and 3B illustrate a non-connection type dot-like protrusion. FIGS. 2A and 3A are perspective views and FIGS. 2B and 3B are section views.

The connection type dot-like protrusion 10a includes cylindrical protrusion bodies 11 and cylindrical small juts 12 formed in the upper central regions of the cylindrical protrusion bodies 11. The protrusion bodies 11 neighboring with each other are connected by means of connection members 13.

On the other hand, the non-connection type dot-like projection 10b includes cylindrical protrusion bodies 11 and cylindrical small juts 12 formed in the upper central regions of the cylindrical protrusion bodies 11. The connection type dot-like protrusion 10a and the non-connection type dot-like projection 10b are distinguished from each other depending on whether the protrusion bodies 11 thereof are connected or separated.

The connection type dot-like protrusion 10a and the non-connection type dot-like projection 10b show a difference in their flow resistances against the heat transfer gas. In the connection type dot-like protrusion 10a, the gas flow path is opened in a direction parallel to the connection direction (in a Y direction in FIG. 2A). Therefore, the flow resistance in that direction is very small. In a direction perpendicular to the connection direction (in an X direction in FIG. 2A), the protrusion bodies 11, the connection members 13 and the small juts 12 act as a gas flow resistance and the gas flow path exists only between the substrate 2 and the protrusion bodies 11 or the connection members 13. Therefore, the flow resistance in the X direction is great.

In contrast, in the non-connection type dot-like projection 10b, the flow resistances in the X and Y directions are all small, which means that the heat transfer gas can flow smoothly.

In case of using a non-connection type projection 10c shown in FIGS. 4A and 4B, the heat transfer gas can flow smoothly in the x and Y directions as in the non-connection type dot-like projection 10b shown in FIGS. 3A and 3B. However, the non-connection type projection 10c shown in FIGS. 4A and 4B differs from the non-connection type dot-like projection 10b shown in FIGS. 3A and 3B in that the flow in the X direction occurs only between the protrusion bodies 11 neighboring with one another and further that the contact area between the substrate 2 and the protrusion bodies 11 becomes greater.

In the mounting table 1 of the present embodiment, the connection type dot-like protrusion 10a and the non-connection type dot-like projection 10b are distinguished when in use and the pressure applied to the substrate 2 are changed on a zone-by-zone basis.

Referring to FIG. 1A, the central blank region surrounded by the outlet ports 7 is a constant-pressure zone 14 where the pressure is kept substantially constant. The non-connection type dot-like projection 10b is arranged along concentric circles in the constant-pressure zone 14. The protrusion bodies 11 have a diameter of about 2 mm and are arranged at an interval of about 1 to 2 mm both in a circumferential direction and in a radial direction. In the constant-pressure zone 14 where the non-connection type dot-like projection 10b is arranged, the gas is allowed to smoothly flow in the X and Y directions. Therefore, the pressure of the heat transfer gas in the constant-pressure zone 14 is maintained substantially constant.

In a gradient pressure zone 15, the connection type dot-like protrusion 10a is arranged along concentric circles and is integrally connected over the full circumference. Such connection bodies are concentrically circumferentially arranged in several tens of lines at a radial interval of 1 to 2 mm. With the connection type dot-like protrusion 10a, the heat transfer gas is hard to flow in the X direction (in the radial direction of the mounting table) but is free to flow in the Y direction (in the circumferential direction of the mounting table) as shown in FIG. 2A. Therefore, in the gradient pressure zone 15, the pressure of the heat transfer gas in the circumferential direction is rendered uniform but a difference in the pressure of the heat transfer gas is generated in the radial direction due to the flow resistance acting against the heat transfer gas introduced through the inlet ports 6.

In other words, the pressure of the heat transfer gas in the hatched region surrounded by the peripheral ridge portion 4 and the outlet ports 7 grows smaller toward the center of the mounting table 1. For that reason, the region (hatched region) between the inlet ports 6 and the outlet ports 7 constitutes the gradient pressure zone 15 where the pressure of the heat transfer gas is gradually varied.

Even if the connection type dot-like protrusion 10a or the non-connection type dot-like projection 10b is provided in plural numbers on the upper surface of the mounting table 1, a space continuously extending over the nearly whole surface of the substrate 2 is formed by the gap 3. In other words, despite the fact that those obstacles such as the dot-like protrusion, the peripheral ridge portion and the like exist within the gap 3, the flow path of the heat transfer gas is formed over the nearly whole surface of the substrate 2 (except the outermost periphery). In this manner, it is possible to form the flow path of the heat transfer gas.

In this regard, one of the features of the present invention resides in that a pressure difference is intentionally generated between the inlet ports 6 arranged near the peripheral ridge portion 4 and the outlet ports 7 arranged near the center of the mounting table 1. Although a steady gas stream is generated between the inlet ports 6 and the outlet ports 7, it is preferred that a flow rate controller 9 is provided in order to control the differential pressure to a desired value.

The purpose of generating the differential pressure in this manner is to vary the heat dissipation amount in the peripheral edge region and the central region of the substrate 2. This is because the gas flow between the mounting table and the substrate is often in a molecular flow regime and the heat transfer rate of the gas in the molecular flow regime is proportional to the pressure.

In the present embodiment, the heat transfer gas was allowed to flow in such a manner that the pressure within the gap 3 varies in the peripheral edge region and the central region of the substrate 2. Investigation was conducted to know in what pattern the temperature of the substrate 2 is changed (which investigation will be referred to as a temperature measurement test). Prior to conducting the temperature measurement test, it was tested whether the pressure within the gap 3 is controllable (which test will be referred to as a pressure control test).

FIG. 5 is a view for explaining how to conduct the pressure control test. In the substrate mounting surface, six holes of 0.8 mm in diameter were formed as inlet and outlet ports of the heat transfer gas, respectively in the substrate edge side region and the substrate center side region. The test was conducted at a chamber pressure of about 50 mTorr.

As shown in FIG. 5, the substrate center side (hereinafter, referred to as “center side”) inlet and outlet holes 16a are formed in radial positions about 40 mm away from the center C of the substrate 2. The substrate edge side (hereinafter, referred to as “edge side”) inlet and outlet holes 16b are formed in radial positions about 100 mm away from the center C of the substrate 2. The substrate 2 has a radius of 150 mm.

The center side inlet and outlet holes 16a and the edge side inlet and outlet holes 16b are respectively connected to gas flow meters 17a and 17b. Branch pipes are provided near the exits of the inlet and outlet holes 16a and 16b. The branch pipes are respectively connected to manometers 18a and 18b.

Four pressure patterns were set as target pressures as follows:

(A1) low pressure in the center side (5 Torr)/low pressure in the edge side (5 Torr);

(A2) low pressure in the center side (5 Torr)/middle pressure in the edge side (15 Torr);

(A3) middle pressure in the center side (15 Torr)/low pressure in the edge side (5 Torr); and

(A4) middle pressure in the center side (15 Torr)/middle pressure in the edge side (15 Torr).

Investigation was conducted to know the flow rate of the heat transfer gas that needs to be introduced through the center side and edge side inlet and outlet holes 16a and 16b to achieve the target pressures noted above.

The results of measurement of the flow rate required in achieving the above-noted pressures are shown in Table 1.

TABLE 1

| | Center Side | Edge Side | Center Side | Edge Side |
|---|---|---|---|---|
| | Pressure | Pressure | Flow Rate | Flow Rate |
| No. | (Torr) | (Torr) | (sccm) | (sccm) |
| A1 | 5 | 5 | 5.3 | 5.4 |
| A2 | 5 | 15 | 2.3 | 34.4 |
| A3 | 15 | 5 | 33.9 | 2.5 |
| A4 | 15 | 15 | 32.0 | 32.3 |

It is apparent in Table 1 that the balance of the center side pressure and the edge side pressure can be arbitrarily changed by changing the introduction quantity of the heat transfer gas and further that the pressure becomes approximately 5 Torr at a gas flow rate of about 2 sccm to 5 sccm (cc/min in a standard state) and approximately 15 Torr at a gas flow rate of about 30 sccm to 35 sccm.

The results noted above reveal that it is possible to control the pressure distribution within the gap 3 to a desired value. Subsequently, the temperature distribution in the substrate 2 was measured with respect to the three pressure patterns:

(B1) low pressure in the center side (10 Torr)/high pressure in the edge side (40 Torr);

(B2) high pressure in the center side (40 Torr)/low pressure in the edge side (10 Torr); and

(B3) middle pressure in the center side (25 Torr)/middle pressure in the edge side (25 Torr).

(Temperature Measurement Test)

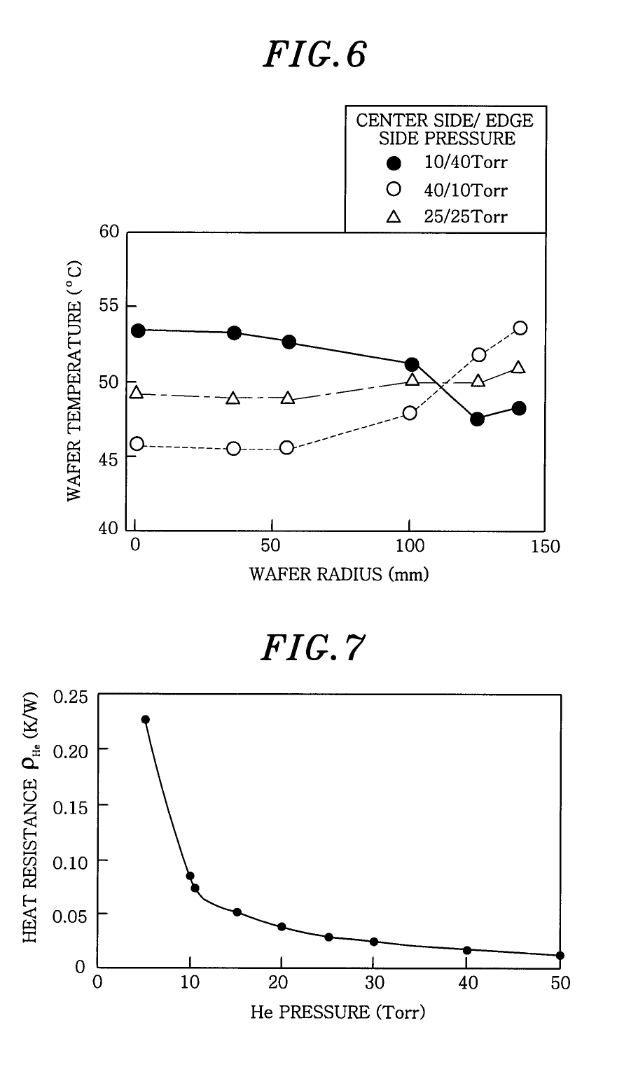

Measurement of the substrate temperature was performed by measuring the temperature of the substrate surface at seven radial points having different distances from the center under the actual plasma processing conditions. The PlasmaTemp SensorWafer, a product of OnWafer Technologies, Inc., was used in the temperature measurement. The results of measurement are shown in FIG. 6.

As shown in FIG. 6, the radial temperature distribution of the substrate is generally uniform and equal to about 50° C. under the B3 condition (indicated by symbol A in FIG. 6) in which the center side pressure and the edge side pressure are kept equal. The temperature is slightly increased as the measurement points get nearer to the edge. The temperature in the edge is about 2° C. higher than the temperature in the center. This is due to the appearance of a general tendency that the cooling intensity in the edge side region is a little bit weaker than in the center side region.

In contrast, the center side temperature is approximately 54° C. but the edge side temperature is approximately 49° C. under the B1 condition (indicated by symbol in FIG. 4) in which the center side pressure is low and the edge side pressure is high. This indicates that the cooling intensity in the edge side region is stronger than in the center side region.

In case of the B2 condition (indicated by symbol ∘ in FIG. 6) in which the center side pressure is high and the edge side pressure is low, the center side temperature is approximately 46° C. The temperature is increased as the measurement points get nearer to the edge side, which means that the cooling intensity in the center side region is stronger than in the edge side region. These measurement results reveal that the cooling effect offered by the heat transfer gas grows higher and the substrate temperature becomes lower in the region where the pressure within the gap 3 is kept higher.

The radial temperature distribution in the substrate is substantially uniform in the range where the radius r is equal to 0 to 40 mm. A temperature gradient occurs in the range where the radius r is equal to 40 to 150 mm. It is thought that this reflects the pressure distribution. In other words, the range where the radius r is equal to 0 to 40 mm is considered to be a constant pressure zone in which the pressure is substantially constant. The range where the radius r is equal to 40 to 150 mm is considered to be a gradient pressure zone in which the pressure is gradually changed.

In the present invention, it is preferred that the differential pressure between the inlet ports and the outlet ports is set in a range of from 10 Torr to 40 Torr. The reasons for this will be described herein below.

Assuming that the heat is conductively transferred from the whole surface of the substrate to the mounting table through the He gas layer, the heat conduction quantity Q (J) is given by the equation (1):

Q=A·λ·(ΔT/d)·t (1),

where the A is a heat conduction area (m²), the λ is a heat conduction rate (W/m·K), the ΔT is a temperature difference (K) between the substrate and the mounting table, the d is a distance (m) between the substrate and the mounting table, and the t is a heat conduction time (s).

Now, if the inverse number of (Aλ/d) is a heat resistance ρ_{He} (=d/Aλ), the equation Q/t=ΔT/ρ_{He} is established. It is easy to evaluate the heat conduction if the ρ_{He} is known. In the present embodiment, given A=0.0593 m² and d=40×10⁻⁶ m, the ρ_{He} is found by calculating the relationship between the heat conduction rate λ and the pressure ρ_{He} of He gas.

FIG. 7 represents the relationship between a heat resistance ρ_{He} and a He pressure. As represented in FIG. 7, when the He pressure is equal to or smaller than 10 Torr, the heat resistance ρ_{He} is sharply increased along with the reduction in the He pressure. The heat resistance ρ_{He} is gently decreased if the He pressure exceeds 10 Torr. Little decrease in the heat resistance ρ_{He} occurs if the He pressure exceeds 40 Torr. Therefore, with a view to reduce the heat resistance ρ_{He} as far as possible, it is desirable that the differential pressure between the inlet ports and the outlet ports be set in a range of from 10 Torr to 40 Torr.

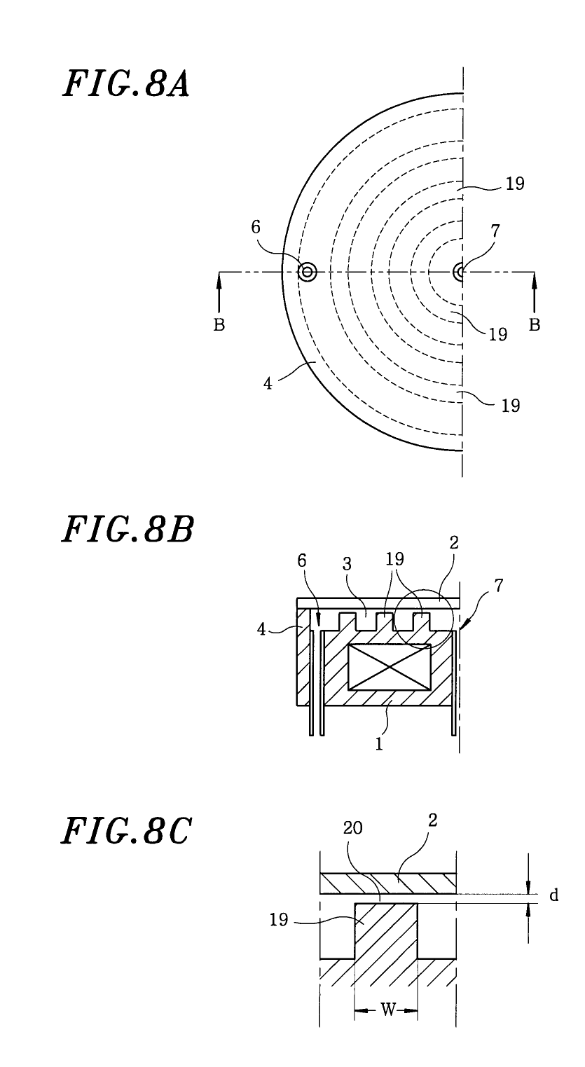

FIGS. 8A, 8B and 8C are views showing a substrate mounting table in accordance with a second embodiment of the present invention. FIG. 8A is a plan view of the substrate mounting table (illustrating the left half thereof), FIG. 8B is a section view taken along line B-B in FIG. 8A, and FIG. 8C is an enlarged view of the portion designated by C in FIG. 8B.

In the second embodiment, a substrate 2 is mounted on an annular peripheral ridge portion 4 of a mounting table 1. A gap 3 through which a heat transfer gas flows is formed between the surface of the mounting table 1 and the substrate 2. A heat transfer gas inlet port 6 is formed near the peripheral edge of the mounting table 1 and a heat transfer gas outlet port 7 is formed in the central region of the mounting table 1, as is the case in the first embodiment shown in FIG. 1.

The second embodiment differs from the first embodiment in that, in place of the connection type or non-connection type dot-like projection 10a or 10b shown in FIG. 2, a plurality of annular projection portions 19 is concentrically formed about the center of the mounting table 1.

Each of the annular projection portions 19 has a planar upper surface. A gap 20 having a height d is formed between the annular projection portions 19 and the substrate 2.

A heat transfer gas flow path is formed between the annular projection portions 19 so that the heat transfer gas can easily flow in the circumferential direction. Thus, the heat transfer gas introduced from the inlet port 6 flows along the circumferential direction and then goes over the gap 20 into the next flow path. After repeating this flow actions, the heat transfer gas is discharged through the outlet port 7 provided in the central region of the mounting table 1.

If the heat transfer gas is allowed to steadily flow at a specified flow rate between the inlet port 6 and the outlet port 7, a differential pressure ΔP is generated between the inlet port 6 and the outlet port 7. The substrate region where the pressure of the heat transfer gas remains high is heavily cooled but the substrate region where the pressure of the heat transfer gas remains low is weakly cooled.

The mounting table 1 of the second embodiment is advantageously used in keeping the flow rate of the heat transfer gas low and generating a high differential pressure. In this type of flow path, the differential pressure is generated predominantly in the gap 20. Crucial factors affecting the differential pressure ΔP include the number n of the annular projection portions 19, the width w of the annular projection portions 19, the height d of the gap 20, and so forth. If the height d is set small, it becomes possible to increase the differential pressure ΔP with a reduced flow rate.

The relationship between the differential pressure ΔP and the flow rate Q in a molecular flow regime is given by the equation (2):

ΔP=Q/C (2),

where the ΔP is a differential pressure (Pa) between the inlet port and the outlet port, the Q is a mass flow rate (Pa·m³/sec) of the heat transfer gas, and the C is a conductance (m³/sec).

Since the helium gas used as the heat transfer gas is expensive, it is preferable to reduce the flow rate Q as far as possible. Preferably, the flow rate Q is equal to or less than 100 sccm (cc/min in a standard state). Seeing that it becomes difficult to control the flow rate Q if the flow rate Q is extremely small, the practically desirable range of the flow rate Q is 1 sccm to 100 sccm. As already mentioned, the upper limit value of the differential pressure ΔP is preferably 40 Torr. The desirable value of the conductance C is calculated using the equation (2). The flow rate of 1 sccm calculated in terms of the unit of Q is represented as follows.

Q: 1 sccm=1.689×10³ Pa·m³/sec

Further, the differential pressure is given as follows.

ΔP: 40 Torr=(40/760)×1.013×10⁵=5333 Pa

Accordingly, C=Q/ΔP=(1 to 10 sccm)×(1.689×10⁻³)/(5333), which is nearly equal to (1 to 100)×0.317×10⁻⁶ m³/sec.

In other words, the conductance C may be set equal to about 3×10⁻⁷ m³/sec in order to generate a differential pressure of 40 Torr by using a He flow rate of 1 sccm. Likewise, the conductance C may be set equal to about 3×10⁻⁵ m³/sec in order to generate a differential pressure of 40 Torr by using a He flow rate of 100 sccm.

In the mounting table of the second embodiment, the conductance C can be made smaller by reducing the height d of the gap 20. Furthermore, the conductance C is greatly changed by changing the n, W and d noted above. This means that it is possible to render the conductance C equal to the desired value mentioned above by suitably adjusting the n, W and d.

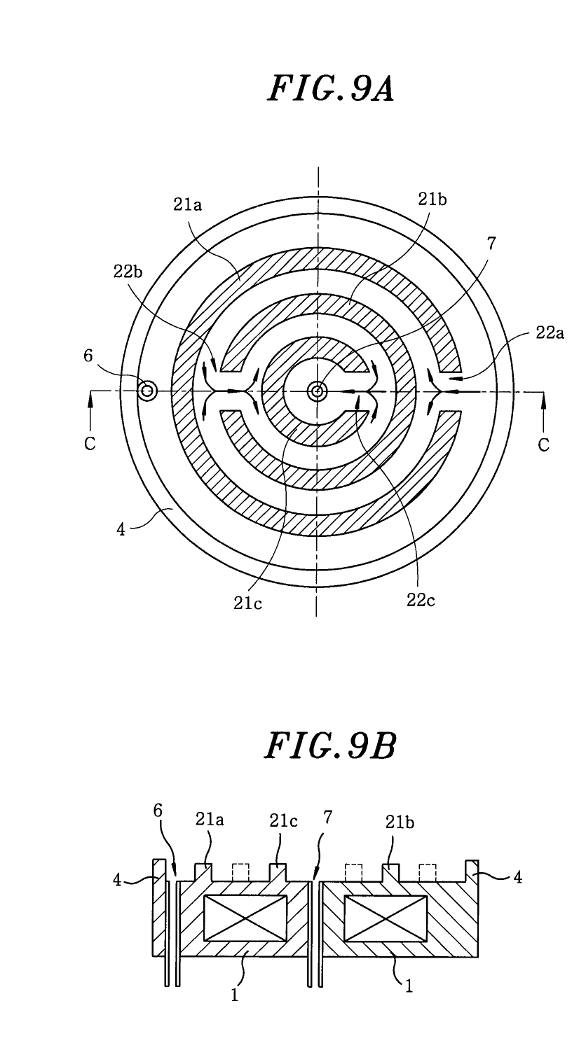

FIGS. 9A and 9B are views showing a substrate mounting table in accordance with a third embodiment of the present invention. FIG. 9A is a plan view of the substrate mounting table (on which no substrate is mounted) and FIG. 9B is a section view taken along line C-C in FIG. 9A.

In the peripheral edge of a mounting table 1, there is provided an annular peripheral ridge portion 4 on which a substrate is mounted. Just like the preceding embodiments, a heat transfer gas inlet port 6 is formed near the peripheral edge of the mounting table 1 and a heat transfer gas outlet port 7 is formed in the central region of the mounting table 1.

In the present embodiment, three generally circular partition walls 21a to 21c are concentrically provided on the upper surface of the mounting table 1. The upper surfaces of the partition walls 21a to 21c make contact with the substrate without leaving any gap between the substrate and the partition walls 21a to 21c. Therefore, the heat transfer gas is kept from flowing therebetween. The heat transfer gas is allowed to flow through a cutout portion formed at a single point in each of the partition walls 21a to 21c.

More specifically, the outer partition wall 21a has a cutout portion 22a formed on the opposite side from the inlet port 6 (on the right side). The intermediate partition wall 21b has a cutout portion 22b formed on the side closer to the inlet port 6 (on the left side). The inner partition wall 21c has a cutout portion 22c formed on the opposite side from the inlet port 6 (on the right side). This ensures that the gas flows along the 180 degree circumferential extensions of the respective partition walls 21a to 21c before it goes inwardly. Thus, the gas flow path is rendered longest.

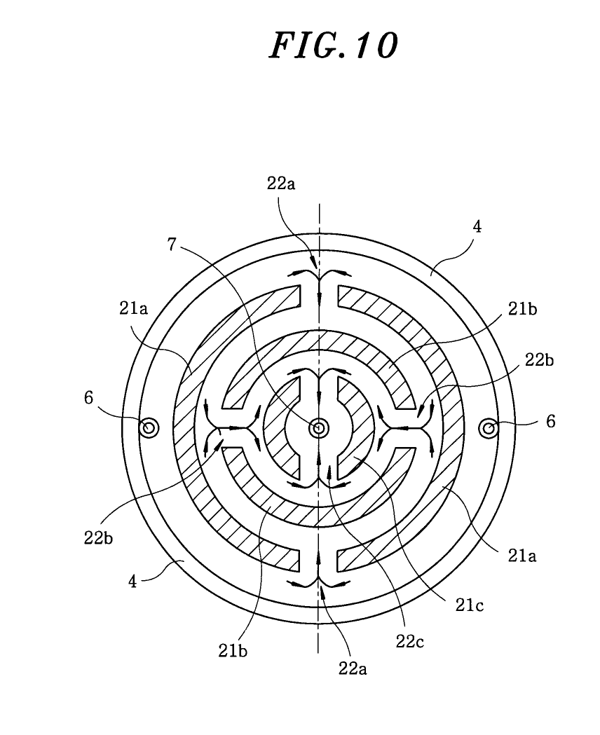

FIG. 10 is a plan view showing a substrate mounting table in accordance with a fourth embodiment of the present invention, with no substrate mounted on the substrate mounting table.

On the peripheral edge of a mounting table 1, there is provided an annular peripheral ridge portion 4 on which a substrate is mounted. As similarly in the embodiment shown in FIG. 9, a heat transfer gas inlet port 6 is formed near the peripheral edge of the mounting table 1 and a heat transfer gas outlet port 7 is formed in the central region of the mounting table 1. Furthermore, three generally circular partition walls 21a to 21c are provided on the upper surface of the mounting table 1 concentrically. In the present embodiment, however, two inlet ports 6 are formed in the mounting table 1. Therefore, the number and position of the cutout portions 22a to 22c differs from that of the embodiment shown in FIG. 9.

More specifically, the outer partition wall 21a has two cutout portions 22a formed on the sides 90 degree deviated from the inlet ports 6 (on the upper and lower sides). The intermediate partition wall 21b has two cutout portions 22b formed on the sides closer to the inlet ports 6 (on the left and right sides). The inner partition wall 21c has two cutout portions 22c formed on the sides 90 degree deviated from the inlet ports 6 (on the upper and lower sides).

The gas introduced from the inlet ports 6 moves along the 90 degree extensions of the outer partition wall 21a and goes inwardly through the cutout portions 22a. Then, the gas moves along the 90 degree extensions of the intermediate partition wall 21b and goes inwardly through the cutout portions 22b. Thereafter, the gas moves along the 90 degree extensions of the inner partition wall 21c and goes inwardly through the cutout portions 22c. Eventually, the gas is discharged through the outlet port 7 formed in the central region of mounting table 1. In this case, the gas flow path is rendered longer.

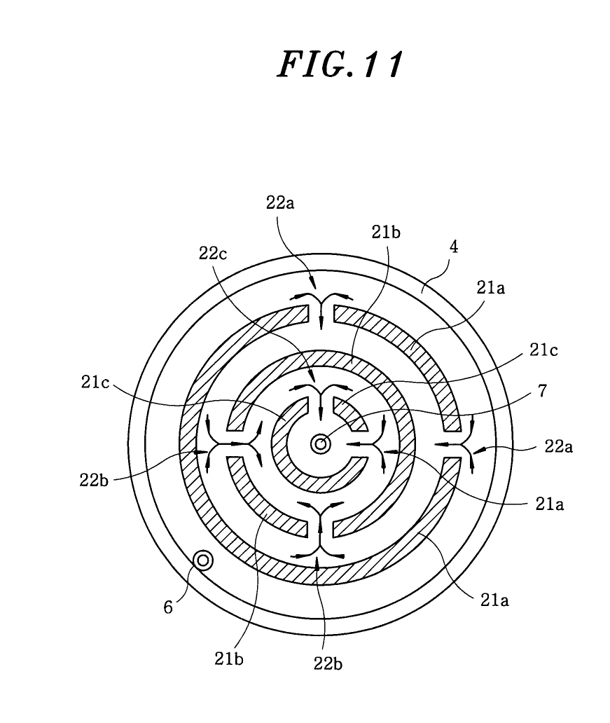

FIG. 11 illustrates a modified example of the embodiment shown in FIG. 10. In the fourth embodiment shown in FIG. 10, each of the partition walls 21a to 21c has two cutout portions 22a, 22b or 22c formed at two points 180 degree deviated from each other. In contrast, the outer partition wall 21a has a first and second cutout portions 22a formed in positions 45 degrees spaced apart from the position opposite from the inlet port 6 clockwise and counterclockwise, respectively. The intermediate partition wall 21b has two cutout portions 22b positioned farthest from the corresponding cutout portions 22a of the outer partition wall 21a. This holds true in case of the cutout portions 22c of the inner partition wall 21c.

The present invention is not limited to the foregoing embodiments. Each of the partition walls may have three or more cutout portions. Additional cutout portions may be provided in arbitrary angular positions deviated clockwise from a particular cutout portion.

The embodiments shown in FIGS. 9A, 9B, 10 and 11 have features that the gas flow path extending from the heat transfer gas inlet port(s) 6 formed in the peripheral edge region to the heat transfer gas outlet port 7 formed in the center region is prolonged. The gas flow path is further lengthened if the number of partition wall is increased.

If a resistant body for generating the differential pressure, e.g., the connection type dot-like protrusion 10a shown in FIG. 2A, is arranged in plural numbers in the gas flow path, there is provided an advantage in that an increased differential pressure can be generated with a reduced gas flow rate.

While the invention has been shown and described with respect to the embodiments, it will be understood by those skilled in the art that various changes and modification may be made without departing from the scope of the invention as defined in the following claims.

What is claimed is:

1. A substrate mounting table for mounting a substrate in a substrate processing apparatus, comprising:
a table body having a substrate mounting surface; and
an annular peripheral ridge portion formed on the substrate mounting surface of the table body for making contact with a peripheral edge portion of the substrate and for forming a closed space for circulation of a heat transfer gas below the substrate, when the substrate is mounted on the substrate mounting surface of the table body;
wherein the table body has a heat transfer gas inlet port formed in one of a peripheral edge region and a central region of the substrate mounting surface, a heat transfer gas outlet port formed in the other of the peripheral edge region and the central region of the substrate mounting surface, and a flow path formed on the substrate mounting surface for forming a conductance C when the heat transfer gas flows from the inlet port to the outlet port.

2. The substrate mounting table of claim 1, wherein the conductance C is within a desired range and is defined by equation (1):
C (m³/sec)=Q/ΔP (1),
where the Q is a mass flow rate (Pa m³/sec) of the heat transfer gas and the ΔP is a differential pressure (Pa) between the inlet port and the outlet port.

3. The substrate mounting table of claim 1, wherein the flow path is formed by flow path forming members concentrically arranged in plural lines, each of the flow path forming members including protrusion bodies and connection members interconnecting the protrusion bodies, the protrusion bodies being provided in close proximity to the substrate without contacting therewith.

4. The substrate mounting table of claim 1, wherein the flow path is formed by flow path forming members concentrically arranged in plural lines, each of the flow path forming members including protrusion bodies and connection members interconnecting the protrusion bodies, each of the protrusion bodies having thereon a relatively small jut that makes contact with the substrate.

5. The substrate mounting table of claim 1, wherein the conductance C is in a range of from 3×10⁻⁸ m³/sec to 3×10⁻⁴ m³/sec.

6. The substrate mounting table of claim 1, wherein the conductance C is in a range of from 3×10⁻⁷ m³/sec to 3×10⁻⁵ m³/sec.

7. The substrate mounting table of claim 1, wherein a heat transfer gas pressure difference between the inlet port and the outlet port falls within a range of from 10 Torr to 40 Torr.

8. The substrate mounting table of claim 7, wherein the flow path is formed to ensure that the heat transfer gas pressure difference between the inlet port and the outlet port falls within the range of from 10 Torr to 40 Torr when the heat transfer gas flows at a flow rate of 1 sccm to 100 sccm.

9. A substrate mounting table for mounting a substrate in a substrate processing apparatus, comprising:
a table body having a substrate mounting surface; and
an annular peripheral ridge portion formed on the substrate mounting surface of the table body for making contact with a peripheral edge portion of the substrate and for forming a closed space for circulation of a heat transfer gas below the substrate, when the substrate is mounted on the substrate mounting surface of the table body,
wherein the table body includes: a heat transfer gas inlet port and a heat transfer gas outlet port one of which is formed at a position spaced by a distance r away from the center point of the substrate mounting surface and the other one is formed in a peripheral edge region of the substrate mounting surface; a flow path formed on the substrate mounting surface for forming a conductance C when the heat transfer gas flows from the inlet port to the outlet port; and a plurality of dot-like protrusions arranged in a range between the center point of the substrate mounting surface and the position spaced by the distance r away from the center point.

10. The substrate mounting table of claim 9, wherein the conductance C is within a desired range and is defined by equation (1):
C (m³/sec)=Q/ΔP (1),
where the Q is a mass flow rate (Pa·m³/sec) of the heat transfer gas and the ΔP is a differential pressure (Pa) between the inlet port and the outlet port.

11. The substrate mounting table of claim 9, wherein the flow path is formed by flow path forming members concentrically arranged in plural lines, each of the flow path forming members including protrusion bodies and connection members interconnecting the protrusion bodies, the protrusion bodies being provided in close proximity to the substrate without contacting therewith.

12. The substrate mounting table of claim 9, wherein the flow path is formed by flow path forming members concentrically arranged in plural lines, each of the flow path forming members including protrusion bodies and connection members interconnecting the protrusion bodies, each of the protrusion bodies having thereon a relatively small jut that makes contact with the substrate.

13. The substrate mounting table of claim 9, wherein the conductance C is in a range of from 3×10⁻⁸ m³/sec to 3×10⁻⁴ m³/sec.

14. The substrate mounting table of claim 9, wherein the conductance C is in a range of from 3×10⁻⁷ m³/sec to 3×10⁻⁵ m³/sec.

15. The substrate mounting table of claim 9, wherein a heat transfer gas pressure difference between the inlet port and the outlet port falls within a range of from 10 Torr to 40 Torr.

16. The substrate mounting table of claim 15, wherein the flow path is formed to ensure that the heat transfer gas pressure difference between the inlet port and the outlet port falls within the range of 10 Torr to 40 Torr when the heat transfer gas flows at a flow rate of 1 sccm to 100 sccm.

17. A substrate mounting table for mounting a substrate in a substrate processing apparatus, comprising:
a table body having a substrate mounting surface;
an annular peripheral ridge portion formed on the substrate mounting surface of the table body for making contact with a peripheral edge portion of the substrate and for forming a closed space for circulation of a heat transfer gas below the substrate, when the substrate is mounted on the substrate mounting surface of the table body; and
a plurality of generally circular partition walls concentrically arranged within the closed space for forming a flow path of the heat transfer gas,
wherein the table body includes: a heat transfer gas inlet port formed in one of a peripheral edge region and a central region of the substrate mounting surface; and a heat transfer gas outlet port formed in the other of the peripheral edge region and the central region of the substrate mounting surface, and wherein each of the partition walls has a cutout through which the heat transfer gas flows.

18. The substrate mounting table of claim 17, wherein the conductance C is within a desired range and is defined by equation (1):
C (m³/sec)=Q/ΔP (1),
where the Q is a mass flow rate (Pa m³/sec) of the heat transfer gas and the ΔP is a differential pressure (Pa) between the inlet port and the outlet port.

19. The substrate mounting table of claim 17, wherein the partition walls are in close proximity to the substrate without contacting therewith.

20. The substrate mounting table of claim 17, wherein the partition walls are in contact with the substrate.

21. The substrate mounting table of claim 17, wherein the conductance C is in a range of from 3×10⁻⁸ m³/sec to 3×10⁻⁴ m³/sec.

22. The substrate mounting table of claim 17, wherein the conductance C is in a range of from 3×10⁻⁷ m³/sec to 3×10⁻⁵ m³/sec.

23. The substrate mounting table of claim 17, wherein a heat transfer gas pressure difference between the inlet port and the outlet port falls within a range of from 10 Torr to 40 Torr.

24. The substrate mounting table of claim 23, wherein the flow path is formed to ensure that the heat transfer gas pressure difference between the inlet port and the outlet port falls within the range of 10 Torr to 40 Torr when the heat transfer gas flows at a flow rate of 1 scam to 100 sccm.

25. A substrate processing apparatus comprising:
a processing chamber for receiving a substrate, the processing chamber having an internal space kept under a reduced pressure;
the substrate mounting table of claim 1 provided within the processing chamber for mounting the substrate;
a processing mechanism for subjecting the substrate to a specified treatment within the processing chamber; and
a heat transfer gas supplying mechanism for supplying a heat transfer gas to a closed space formed between the substrate mounting table and the substrate mounted thereon.

26. The substrate processing apparatus of claim 25, further comprising a control mechanism for controlling the pressure of the heat transfer gas supplied from the heat transfer gas supplying mechanism.

27. A substrate temperature control method for controlling the temperature of a substrate using the substrate mounting table of claim 1, which comprises:
controlling the flow rate of a heat transfer gas to ensure that a heat transfer gas pressure difference between the inlet port and the outlet port becomes equal to 10 Torr to 40 Torr, when the conductance C is within a range of from 3×10⁻⁷ m³/sec to 3×10⁻⁵ m³/sec.

28. A substrate temperature control method for controlling the temperature of a substrate using the substrate mounting table of claim 3, which comprises:
adjusting the conductance C by changing the height of a gap between the flow path forming members and the substrate and/or the number of lines of the concentrically arranged flow path forming members.

29. A substrate temperature control method for controlling the temperature of a substrate using the substrate mounting table of claim 4, which comprises:
adjusting the conductance C by changing the height and width of the small jut and/or the number of lines of the concentrically arranged flow path forming members having the small jut.

30. A substrate temperature control method for controlling the temperature of a substrate by using the substrate mounting table of claim 20, which comprises:
adjusting the conductance C by changing the number of lines of the concentrically arranged partition walls.

31. A substrate temperature control method for controlling the temperature of a substrate using the substrate mounting table of claim 19, which comprises:
adjusting the conductance C by changing the height of a gap between the concentrically arranged partition walls and the substrate and/or the number of lines of the concentrically arranged partition walls.
